(19) United States
(12) Patent Application Publication
(10) Pub. No.: US 2025/0019826 A1
(43) Pub. Date: Jan. 16, 2025

(54) DEPOSITION OF ULTRA-THIN FUNCTIONAL COATINGS ON FLEXIBLE MATERIALS

(71) Applicant: NFINITE NANOTECHNOLOGY INC., Waterloo (CA)

(72) Inventors: Jhi Yong LOKE, Kitchener (CA); Chee Hau TEOH, Kitchener (CA); Kevin MUSSELMAN, Waterloo (CA)

(21) Appl. No.: 18/713,371

(22) PCT Filed: Nov. 24, 2022
(86) PCT No.: PCT/IB2022/061404

§ 371 Date: May 24, 2024

Related U.S. Application Data
(60) Provisional application No. 63/282,896, filed on Nov. 24, 2021.

(51) Int. Cl. C23C 16/455; C23C 16/40; C23C 16/54

(52) U.S. Cl. CPC C23C 16/45548; C23C 16/545; C23C 16/40

(57) ABSTRACT

An apparatus and method for depositing functional coatings with different formulations on flexible materials is disclosed. Spatial atomic layer deposition produces dense coatings with few or no pinholes that are conformal to the underlying flexible substrate, which enhances the functional properties of the coatings. The apparatus and method can produce coatings that are single-layer or multi-layer and that have one or more functions. The apparatus and method operate in atmospheric conditions and can be used in a stand-alone or in-line manufacturing process. Spatial atomic layer deposition of metal-oxide barrier coatings on packaging materials is disclosed. The metal-oxide barrier coatings provide superior barrier properties to protect the products in the packaging, may perform additional functions, and may be sufficiently thin that they do not compromise the recyclability and/or compostability and/or biodegradability of sustainable packaging materials.

### CROSS-REFERENCE TO RELATED APPLICATIONS

This application claims priority to and the benefit of U.S. provisional patent application No. 62/282,896, filed Nov. 24, 2021, which is incorporated herein by reference.

### FIELD

This disclosure relates to thin film deposition and the coating of flexible materials.

### BACKGROUND

Ultra-thin functional coatings are used on flexible materials for a wide range of packaging applications. Examples include, but are not limited to, coatings that protect the products contained in the packaging (e.g., foodstuffs) from external factors, coatings that provide antimicrobial properties (e.g., packaging for healthcare products), and coatings that enable the integration of energy-harvesting, sensing, and display properties into smart packaging materials.

Barrier coatings are used on flexible packaging materials to protect products (e.g., foodstuffs) from external factors that include, but are not limited to, water vapor, water, oxygen, light, aromas, grease, and foreign matter. Protection from these external factors is useful to extend the shelf-life of the product and ensure it is safe for use or consumption. Examples of current barrier coatings include Polyvinylidene Dichloride (PVDC), Ethylene Vinyl Alcohol (EVOH), and metallization (metal or metal-oxide coatings). Examples of metal and metal-oxide barrier coatings include aluminum, aluminum oxide, and silicon oxide.

Film-producing companies may produce flexible packaging materials and applying barrier coatings. FIG. 1 is a diagram illustrating a conventional flexible-packaging process. In Step 1, a roll of flexible material is produced. An example of a process for producing a flexible material is the blown/cast extrusion process, whereby a resin material is fed into a blown extruder and then fed through a series of rollers (e.g., collapsing frame, nip rolls, idler rolls, dancer rolls, and winder) to convert the resin into a roll of flexible material.

In Step 2 of FIG. 1, a barrier-coating is deposited on the roll of flexible material. The conventional process for depositing a metal or metal-oxide barrier coating involves the following:

Step 1: A roll of flexible material is loaded into a vacuum chamber with a series of rollers for unwinding and rewinding the material. A plating drum is located between the unwinding and rewinding rollers.

Step 2: Coating material may also be introduced into the vacuum chamber.

Step 3: Air is evacuated from the chamber.

Step 4: The flexible material is unwound from the unwinding roller and wound onto the rewinding roller, resulting in it passing over the plating drum.

Step 5: A coating process (e.g., reactive evaporation, thermal evaporation, electron-beam evaporation, plasma-enhanced chemical vapor deposition) is used to coat a barrier coating (e.g., a metal or metal-oxide thin film) on the flexible material as the material passes over the plating drum. This may involve the introduction of gas(es) (e.g., oxygen) into the chamber. Commonly, the coating is comprised of a single layer of material with water-vapor-barrier and oxygen-barrier properties.

Step 6: The chamber is returned to atmospheric pressure and the coated flexible material is removed.

In addition to applying barrier coatings to the flexible materials, film producers may use additional processes to prepare the flexible materials, which may include, but are not limited to applying additional functional coatings, printing and laminating the packaging materials. The prepared packaging material is shipped to a consumer-packaged-goods (CPG) company, which uses the packaging material to create a finished packaged-good product. An example of a packaging process is the vertical form fill and seal (VFFS) process (Step 3 in FIG. 1). In the VFSS process, the roll of flexible material is fed into a vertical cylindrical hopper to form the shape of the package. The product (e.g., food) is filled into the cylinder. A cutter and sealer are used to cut and seal the flexible material into packaged goods with the product inside. Thereafter, the package good is placed in a box (or another outside packaging product) and shipped out to distributors, stores and/or consumers.

A limitation of the barrier-coating process shown in FIG. 1 (Step 2) is that it is a multi-step batch approach. The film producer must load the roll of packaging material into the chamber, pump the chamber down into a vacuum state, coat the roll of material, and then unload the roll from the chamber. This process is costly (e.g., vacuum equipment is expensive), slow (e.g., time is required to pump the chamber down to vacuum), and creates material waste (e.g., the ends of the roll are not coated). Although there is equipment in the market and research done using atmospheric physical-vapor-deposition and chemical-vapor-deposition techniques, which eliminate the need for a vacuum chamber, these techniques are not designed for high-throughput applications like coating of packaging materials. There is a desire to pursue a more cost-effective barrier-coating process that simplifies the packaging manufacturing process.

### SUMMARY

Disclosed herein is an apparatus and method for high-throughput deposition of ultra-thin functional coatings on flexible materials in open air without a vacuum chamber, where the coating is comprised of one or more layers.

The disclosed apparatus uses a gas delivery system to deliver one or more precursor gases to each of one or more spatial atomic layer deposition (SALD) heads (also termed “coaters” or “coater heads”), and a system of rollers and heaters to transport the flexible material past the heads.

In various embodiments of the disclosed apparatus, all the SALD heads are positioned to coat the same surface of the flexible material. In another embodiment of the disclosed apparatus, one or more of the SALD heads are positioned to coat the opposing surfaces of the flexible material.

In various embodiments of the disclosed apparatus, other equipment may be located adjacent to one or more SALD heads to allow characterization or modification of the flexible material or different layers of the ultra-thin coating.

The disclosed apparatus may be a stand-alone system or a drop-in system that is integrated into a manufacturing line.

In the disclosed method, a flexible material is passed next to the head or heads to deposit one or more layers of an ultra-thin coating via SALD. The number of layers and the thickness of each layer that is deposited can be controlled by the number of SALD heads, the design of each SALD head, including, but not limited to, the number of gas delivery channels in the head, and the selection of precursor gases that are delivered to each reactor, among other operating parameters of the apparatus.

In various embodiments of the disclosed method, the flexible material travels in one direction relative to the SALD heads. In another embodiment of the disclosed method, the direction of travel of the flexible material may vary to enable the deposition of thicker coatings or coatings with variable thicknesses.

The disclosed apparatus and method can be used to coat one or more surfaces of a flexible substrate material, which may have varying surface morphology, with one or more conformal, ultra-thin, functional coatings, where each coating is comprised of one or more layers of elemental or compound materials. The ultra-thin coating or coatings may perform one or more functions or may constitute a component of a device that is manufactured on the surface of the flexible material.

Various embodiments of the present invention include the deposition of a barrier coating (e.g., an ultra-thin metal-oxide coating) on a flexible material such as polyethylene, polypropylene, polylactic acid, paperboard or paper, but not limited to the stated. The coating provides barrier properties to protect the products that are packaged within the flexible material or materials. Barrier in this context typically means water-vapor barrier, oxygen barrier, aroma barrier, grease barrier, or aqueous liquid barrier, but is not limited to the stated.

These barrier properties prevent external factors from entering the package to keep the products fresh and may extend the shelf life of products such as food.

In various embodiments of the disclosed coating, the coating is comprised of a single layer of material, such as aluminum oxide, silicon oxide, or tin oxide, but not limited to the stated. In another embodiment of the disclosed coating, the coating may comprise several layers of different materials, where the thickness of each layer can be controlled by the disclosed method (e.g., 10 nanometers (nm) of aluminum oxide—5 nm of zinc oxide—10 nm of aluminum oxide—5 nm of zinc oxide—10 nm of aluminum oxide—10 nm of cuprous oxide). The different layers of the coating may provide multiple functions that include, but are not limited to, enhanced barrier properties, enhanced mechanical properties, light blocking, and antimicrobial properties.

In various embodiments of the disclosed coating, the coating provides the disclosed function or functions on sustainable packaging materials that are fully recyclable and/or compostable and/or biodegradable without compromising the recyclability and/or compostability and/or biodegradability of the sustainable packaging materials.

According to various aspects of this disclosure, an apparatus includes a conveyance system to transport a flexible substrate along a path, a gas-delivery system configured to deliver gas to the flexible substrate, and a SALD head connected to the gas-delivery system to deliver gas to the flexible substrate. The first SALD head includes a slit positioned adjacent to the path to deliver gas to the flexible substrate under atmospheric conditions. The apparatus further includes a second SALD head connected to the gas-delivery system to deliver gas to the flexible substrate. The second SALD head includes a slit positioned adjacent to the path to deliver gas to the flexible substrate under atmospheric conditions. The first and second SALD heads are arranged along the path to deliver gas to the flexible substrate in sequence to apply a coating to the flexible substrate as the flexible substrate is transported along the path.

The first and second SALD heads may be arranged to deliver gas to a same side of the flexible substrate.

The first and second SALD heads may be arranged to deliver gas to different sides of the flexible substrate.

The conveyance system may be configured to define a reversal in the path.

The first and second SALD heads may be positioned at a same leg of the reversal.

The first and second SALD heads may be positioned at different legs of the reversal.

The reversal may be about 180 degrees.

The gas-delivery system and the first and second SALD heads may be configured to apply gas to form a same layer of the coating.

The gas-delivery system and the first and second SALD heads may be configured to apply gas to form different layers of the coating.

The apparatus may further include a frame to which the conveyance system, gas-delivery system, and first and second SALD heads are attached. The frame may be shaped and sized to be dropped into an existing manufacturing line.

According to various aspects of this disclosure, a method includes arranging a first SALD head and a second SALD head along a path of transport of a flexible substrate, transporting the flexible substrate along the path, and delivering, in sequence, gas to the flexible substrate with the first and second SALD heads under atmospheric conditions to apply a coating to the flexible substrate as the flexible substrate is transported along the path.

The method may further include arranging the first and second SALD heads to deliver gas to a same side of the flexible substrate.

The method may further include arranging the first and second SALD heads to deliver gas to different sides of the flexible substrate.

The method may further include positioning the first and second SALD heads at a same leg of a reversal in the path.

The method may further include positioning the first and second SALD heads at different legs of a reversal in the path.

The method may further include delivering, in sequence, gas to the flexible substrate with the first and second SALD heads under atmospheric conditions to form a same layer of the coating.

The method may further include delivering, in sequence, gas to the flexible substrate with the first and second SALD heads under atmospheric conditions to form different layers of the coating.

The method may further include attaching the first and second SALD heads to a frame and installing the frame and installed first and second SALD heads into an existing manufacturing line.

### BRIEF DESCRIPTION OF THE DRAWINGS

For a clear understanding of the disclosure, some embodiments of the present disclosure are illustrated as an example and are not limited to the figures of the accompanying drawings.

FIG. 1 is a diagram illustrating a conventional flexible-packaging process, including the production of a flexible material (Step 1), barrier coating of the flexible material (Step 2), and product packaging (Step 3). The conventional barrier-coating process for metals or metal-oxides is a batch process performed in a vacuum chamber.

FIG. 2A is a diagram illustrating a temporal atomic layer deposition process.

FIG. 2B is a diagram illustrating a spatial atomic layer deposition (SALD) process.

FIG. 3 is a diagram illustrating the components of a disclosed SALD apparatus.

FIG. 4A is a diagram illustrating the placement of SALD heads on the same side of a flexible material in the disclosed apparatus and method.

FIG. 4B is a diagram illustrating the placement of SALD heads on opposite sides of a flexible material in the disclosed apparatus and method.

FIG. 5 is a diagram illustrating the placement of other pieces of equipment between SALD heads in the disclosed apparatus and method.

FIG. 6A is a diagram illustrating a stand-alone apparatus according to the disclosed invention.

FIG. 6B is a diagram illustrating a drop-in apparatus according to the disclosed invention.

FIG. 7 is a diagram illustrating a number of coating layers and the thickness of each layer being controlled by a specific arrangement of the SALD heads and respective operating parameters.

FIG. 8A is a diagram illustrating a single direction of travel of a flexible material with respect to a SALD head.

FIG. 8B is a diagram illustrating bidirectional travel of a flexible material with respect to a SALD head.

FIG. 8C is a diagram illustrating bidirectional travel of a flexible material with respect to several SALD heads.

FIG. 9A is a diagram illustrating single-layer coatings with multiple functionalities on flexible material produced with the disclosed invention.

FIG. 9B is a diagram illustrating multi-layer coatings with multiple functionalities on flexible material produced with the disclosed invention.

FIGS. 10A-10D are diagrams illustrating a spatial atomic layer deposition process to add a barrier coating to a flexible material.

### DETAILED DESCRIPTION

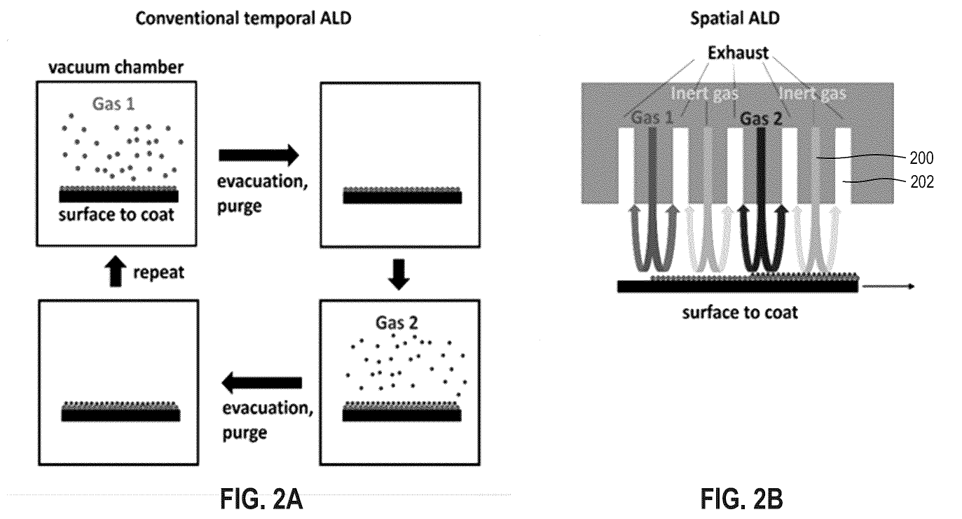

Atomic layer deposition (ALD) is a thin-film deposition technique that can produce excellent barrier coatings, as the coatings can be conformal to the underlying surface and free of pinholes that reduce the barrier performance. Conventional temporal ALD operates by sequentially inserting a chemical precursor gas and reactant gas into a vacuum chamber, with evacuation and purge steps in between the exposures. The conventional temporal ALD process is illustrated in FIG. 2A. If suitable experimental conditions are used, a single atomic layer of the material is formed after each sequence, and the sequence is repeated multiple times to build up a film. However, conventional temporal ALD is a very slow batch process, and it also requires a vacuum chamber, so it is not suitable for high-throughput applications like coating of packaging materials.

Conventional temporal ALD is slow because it separates the precursor and reactant gases in time, via evacuation and purge steps. In contrast, spatial atomic layer deposition (SALD) techniques have been developed, which separate the precursor and reactant gases in space, rather than in time. The surface to be coated is moved between the gases to replicate the sequential exposures. The SALD process is illustrated in FIG. 2B and generally includes ejecting working gas (e.g., precursor gas, reactant gas, inert gas, etc.) via one or more slits 200 and withdrawing exhaust gas via one or more slits 202, in which the slits 200, 202 communicate the gas with a network of channels within a structure that may be termed a SALD coater or head. This eliminates or reduces the evacuation and purge steps that make temporal ALD slow, such that SALD can be one to two orders of magnitude faster than conventional ALD. SALD can produce ultra-thin coatings of materials (e.g. metal oxides) that are compact, conformal, and pinhole-free and can deposit the coatings under open-atmospheric pressures and at room or low temperatures, without the need of vacuum chamber. SALD is scalable and compatible with roll-to-roll manufacturing and has been demonstrated to work on variety of surfaces including, but not limited to, plastics and paper. These advantages make SALD very attractive for high-throughput manufacturing of large-area, low-cost coatings, such as barrier coatings. More information on ALD and SALD can be found in PCT publication WO2021119829, entitled “Apparatus and Method for Thin Film Deposition”, filed on Dec. 18, 2020, which is incorporated herein by reference.

The packaging industry often uses multilayer-structure plastic packaging, which is typically unrecyclable. The industry is moving towards more sustainable solutions, which include but are not limited to, recyclable monolayer-structure plastic packaging, biodegradable materials, thinner plastic, more paper content, elimination of toxicity (e.g., chlorine, BPA), and removal of unsustainable materials (e.g., aluminum). “Sustainable packaging materials” are materials that are fully recyclable and/or compostable and/or biodegradable. However, these sustainable packaging solutions are lacking in barrier performance to protect the products. This is typically, but not limited to, keeping packaged foods fresh by protecting them from external factors such as water, oxygen, light, aromas, and microbes.

Most conventional barrier coatings are not sufficient for use in sustainable packaging to protect products (e.g., food). Polyvinylidene Dichloride (PVDC) is not recyclable, and toxic to the environment. Ethylene Vinyl Alcohol (EVOH) is lacking in certain barrier properties. Plastic packaging with metal coatings (e.g., aluminum) is not recyclable because it is difficult to separate the metal layer from the plastic at the recycling facility. A metal detector at the recycling facility detects the metal and rejects it. A next step in the industry is to use alternative barrier-coating materials that provide superior barrier performance. Metal-oxide barrier coatings, such as aluminum oxide, silicon oxide, titanium dioxide, zinc oxide, and tin oxide can provide excellent barrier performance, even when they are ultra-thin (e.g., 50 nanometers). The very thin nature of the barrier coatings (e.g., less than 100 nanometers) means that the concentration of metal in the packaging would be very low. For example, for a 25 nm aluminum oxide barrier coating on a 100-micrometer packaging material, the concentration of aluminum in the packaging would be several orders of magnitude lower than that in soil. If the materials disintegrate in the environment, some residue from the aluminum oxide barrier would be left, but its concentration is expected to be less than that already present in soils and meet the ASTM D6400-19 criteria for compostability. Metal-oxide coatings are ceramic and inert and do not cause significant harm to the environment when the packaging is composted. Furthermore, since the metal-oxide coatings are non-metallic, they enable the packaging to be recycled. Additional advantages of metal-oxide barrier coatings include, but are not limited to, that the coating is microwaveable and can be transparent (i.e., one can look into the packaging to see the product).

In addition to improved barrier properties, coatings are also desired on sustainable packaging materials to provide additional functionality, such as light-blocking properties, transparency for product-viewing, corrosion-resistance, antimicrobial properties, retortability, friction reduction, energy harvesting, sensing, display features, anti-counterfeiting, and tampering detection. Suitable coatings can accelerate the development of a circular economy for plastic and other packaging materials.

Hence, there is a need for an improved apparatus and method for depositing functional coatings that are ultra-thin, continuous, and conformal onto flexible materials.

The embodiments described herein relate to an ultra-thin functional coating comprised of one or more layers on a flexible substrate material, and the apparatus and method for applying the coating. More specifically, the coating may be an elemental or compound material that performs one or more functions, either on its own or in combination with one or more other components. Functions may include, but are not limited to, water-barrier properties, oxygen-barrier properties, grease-barrier properties, aroma-barrier properties, light-blocking, corrosion resistance, transparency for product-viewing, corrosion resistance, antimicrobial properties, retortability, friction reduction, energy harvesting, sensing, display features, anti-counterfeiting, and tampering detection. The ultra-thin functional coating can be formed during the manufacture of the flexible material or in later manufacturing stages by use of spatial atomic layer deposition techniques.

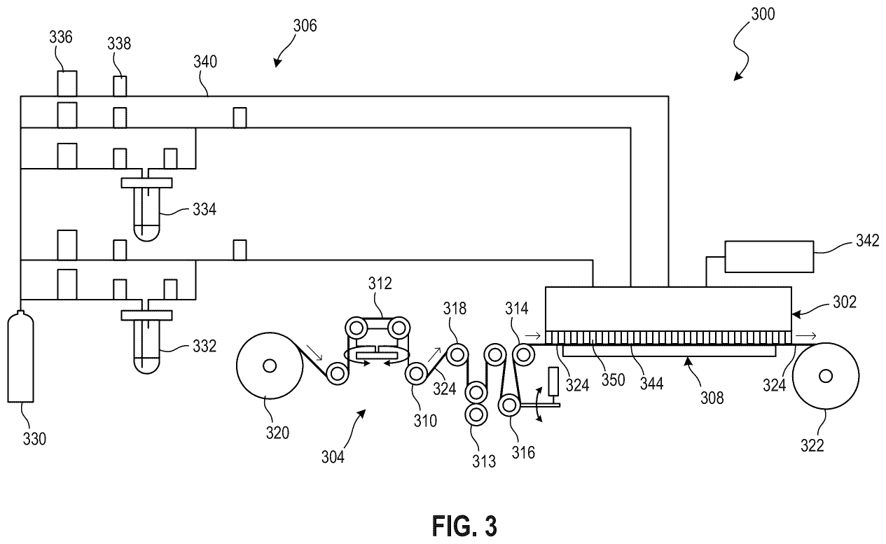

FIG. 3 shows an embodiment of the disclosed spatial atomic layer deposition apparatus 300. Illustrated in FIG. 3 are example components including, but not limited to, at least one SALD head 302, a conveyance system 304, and a gas-delivery system 306. A heater 308 may be provided at the SALD head 302. Any suitable number of SALD heads 302 may be delivered any suitable combination of gases by the gas-delivery system 306 to deposit a coating onto a flexible material conveyed past the SALD head 302 by the conveyance system 304.

The conveyance system 304 may include rollers 310, a web guide 312, nip rollers 313, an idler 314, a dancer 316, a load cell 318, and like components positioned between an unwinder 320 and a winder 322 to convey a flexible substrate material 324, such as a thin sheet or membrane of material (sometimes called a “film,” particularly in the packaging industry, but this is not to be confused with the thin film or coating being deposited). With the convenance system 304, the flexible substrate material 324 may be unwound from a roll at the unwinder 320, coated by the SALD head 302, and wound onto another roll at the winder 322. The positioning of the rollers may be used to position flexible material relative to one or more SALD heads 302 and may be used to control the distance between the surface of the flexible material 324 and the surface of the SALD head 302.

The gas-delivery system 306 includes vessels 330, 332, 334 with inert gas and precursor and reactant chemicals, mass flow controllers 336, on-off valves 338, and gas lines 340 that fluidly connect these components. Each gas line 340 may deliver to the SALD head 302 pure or a mixture of an inert gas, precursor, and reactant, at a flow rate controlled by respective mass flow controller(s) 336 and on-off valve(s) 338. The configuration and arrangement of the components in FIG. 3 represent an example embodiment of the disclosed apparatus. In other embodiments, the components can have different configurations and arrangements.

The gas lines 340 may be tubes made of chemically stable or inert material, such as stainless steel or Teflon, connected between components upstream of the SALD head 302. Such components may include an inert gas vessel 330, chemical-containing vessels (e.g., bubblers) 332, 334, mass flow controllers 336, and on-off valves 338. This gas delivery system 306 serves the purpose of delivering one or more precursor gases, one or more reactant gases, and one or more inert gases, in pure form or suitable mixtures, to the SALD head 302. The inert gas vessel 330 supplies inert, non-reactive gas to the SALD head 302 and may also be used to carry precursor gas from a precursor gas vessel 334 and/or reactant gas from a reactant gas vessel 332 to the SALD head 302. The pressure of the inert gas may be regulated by one or more pressure regulators. The precursor and reactant gases may be generated by techniques such as, but not limited to, bubbling a liquid chemical with the inert gas, nebulizing a liquid chemical, by heating a liquid or solid chemical, or a combination thereof. Chemical vapors may also be supplied in the gaseous state from a storage tank, or generated by another device, such as an ozone generator, which may be used to generate a reactant gas. The flow rates of the inert gas, one or more precursor gases, and one or more reactant gases are controlled by mass flow controllers 336 and on-off valves 338, such as manual diaphragm valves or pneumatic valves. The flow controllers 336 and valves 338 may be controlled manually or electronically by a control system.

Illustrated in FIG. 3, one or more SALD heads 302 deliver a precursor, reactant, and inert gas onto a flexible substrate material 324. The head 302 comprises multiple internal gas channels that redirect and distribute the gases out onto the flexible material 324 in an appropriate arrangement to result in SALD, as illustrated in FIG. 2. The head 302 includes any suitable number and configuration of slits 350 to output gas to the flexible substrate material 324. Other components may be integrated into one or more SALD heads 302, including, but not limited to, cooling and heating elements and plasma sources. For example, one or more plasma sources may be embedded into the head to lower the temperature required for the coating deposition. According to FIG. 3, one or more exhaust pumps 342 are connected to the head 302. The exhaust pump 342 removes gases such as unreacted precursor and/or reactant and inert gas from the space between the operating surface 344 of the head 302 and the surface of the flexible material 324.

Illustrated in FIG. 3, the heater 308 may be used to heat the flexible material 324 to facilitate chemical reactions on the surface of the flexible material 324. In the embodiment shown in FIG. 3, the heater 308 spans the length of the head 302. Various heaters with different heating power and with different shapes and sizes (e.g., a drum heater that the flexible material wraps around) may be provided. Additionally, one or more heaters may be embedded into the head 302. One or more heaters may also be used to control the position of the surface of the flexible material relative to one or more of the SALD heads 302, based on the mechanical positioning of the heater(s). One or more of the rollers of the conveyance system 304 may be heated to control the temperature of the flexible material 324.

In other embodiments of the disclosed apparatus, a sheet or multiple sheets of flexible material can be mounted on a translating stage which moves past the head either in a single-direction or in both directions for the coating process. The translating stage may be heated and may be used to control the distance between the surface of the flexible material and the surface of a SALD head 302.

More information on possible embodiments of the gas delivery system, SALD head(s), exhaust pump(s), heater(s), and translating stage can be found in PCT publication WO2021119829, entitled “Apparatus and Method for Thin Film Deposition”, filed on Dec. 18, 2020 which is incorporated herein by reference.

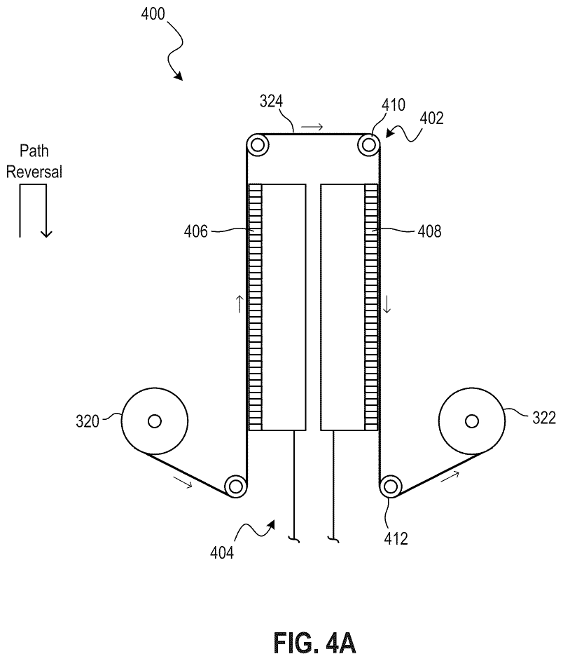

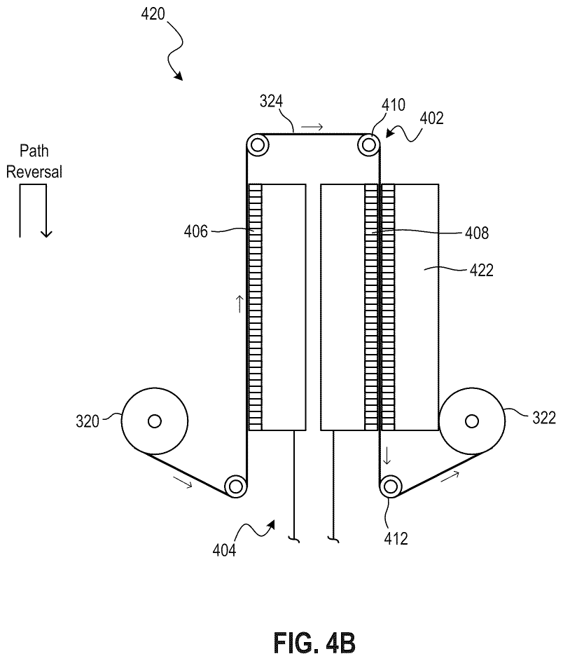

In the disclosed invention, SALD heads can be positioned to coat one or more sides of the flexible material. FIGS. 4A and 4B show examples of how the SALD heads can be positioned relative to the surfaces of the flexible material. In various embodiments of the disclosed invention, all the SALD heads are positioned to coat the same surface of the flexible material. In another embodiment of the disclosed apparatus, one or more of the SALD heads are positioned to coat the opposing surfaces of the flexible material.

As shown in FIG. 4A, an apparatus 400 includes a conveyance system 402 to transport a flexible substrate 324 along a path, a gas-delivery system 404 configured to deliver gas, and a plurality of SALD heads 406, 408 to receive gas from the gas-delivery system 404 and provide the gas to the flexible substrate 324. Any suitable number and configuration of SALD heads 406, 408 may be used.

The conveyance system 402 includes rollers 410, 412 that transport the flexible material 324 past the SALD heads 406, 408. The conveyance system 402 may take the flexible substrate 324 from a stock roll at an unwinder 320 and provide the flexible material 324 to a coated stock roll at a winder 322. Alternatively, for example in manufacturing line that uses the flexible material 324 to make a product, the conveyance system 402 may take the flexible substrate 324 from an upstream process and provide the flexible material 324 to a downstream process. The upstream process may be an unwinder 320 or a process that forms the flexible material 324. The downstream process may be a packaging machine, a machine that applies additional coating, a converting machine, a slitting machine, a printer, etc. In this example, four rollers 410, 412 are positioned to define a reversal for the path followed up the flexible substrate 324. Such a reversal may be a complete turn-around in path of, for example, 180 degrees. FIG. 3 and the related description may be referenced for further detail regarding the conveyance system.

The gas-delivery system 404 provides precursor, reactant, and/or inert gas to the SALD heads 406, 408. The same or different combination of gases may be delivered to each SALD head 406, 408. FIG. 3 and the related description may be referenced for further detail regarding the gas-delivery system.

The first SALD head 406 is connected to the gas-delivery system 404 to deliver gas to the flexible substrate 324. The first SALD head 406 includes any suitable number and configuration of channels and slits positioned adjacent to the path followed by the flexible substrate 324 to deliver gas to the flexible substrate 324 under atmospheric conditions. No chamber, vacuum chamber or otherwise, need be used.

The second SALD head 408 is connected to the gas-delivery system 404 to deliver gas to the flexible substrate 324. The second SALD head 408 includes any suitable number and configuration of channels and slits positioned adjacent to the path to deliver gas to the flexible substrate 324 under atmospheric conditions. Again, no chamber, vacuum chamber or otherwise, need be used.

For sake of clarity, an example of ambient conditions is normal air at a temperature, pressure, and humidity that may be found within a manufacturing plant. Another example of ambient conditions is purified or conditioned air at set temperature, pressure, and humidity conducive to a given manufacturing operation and still able to be breathed.

FIG. 3 and the related description may be referenced for further detail regarding the SALD heads.

The first and second SALD heads 406, 408 are arranged along the substrate conveyance path to deliver gas to the flexible substrate 324 in sequence to apply a coating to the flexible substrate 324 as the flexible substrate 324 is transported along the path by the conveyance system 402. The first and second SALD heads 406, 408 are arranged to deliver gas and thus impart the coating to the same side of the flexible substrate 324. The first and second SALD heads 406, 408 may each receive any suitable combination of precursor, reactant, and inert gas.

The second SALD head 408 is positioned downstream of the first SALD head 406. Thus, the second SALD head 408 may be used to add to the same layer of coating deposited by the first SALD head 406. That is, the second SALD head 408 may build up the same material as formed by the first SALD head 406. Alternatively, the second SALD head 408 may be used to form a layer different from that deposited by the first SALD head 406. That is, the second SALD head 408 may form a coating material different from the coating material formed by the first SALD head 406. Alternatively or additionally, a SALD head 406, 408 may be used to form a multi-layer coating. For example, the first SALD head 406 may be configured to deposit a multi-layer coating using two or more different precursor gasses delivered to the first SALD head 406.

In this example, the first and second SALD heads 406, 408 are positioned at different legs of the reversal of the path. In other words, a portion of the conveyance system 402, such as rollers 410, is positioned between the first and second SALD heads 406, 408 and this changes the direction of movement of the flexible substrate 324. The first and second SALD heads 406, 408 operate on segments of the flexible substrate 324 that are at different locations and, when the path is a complete reversal, these segments are parallel to each other.

As shown in FIG. 4B, an apparatus 420 includes a conveyance system 402 to transport a flexible substrate 324 along a path, a gas-delivery system 404 configured to deliver gas, and a plurality of SALD heads 406, 408, 422 to receive gas from the gas-delivery system 404 and provide the gas to the flexible substrate 324. Any suitable number and configuration of SALD heads 406, 408, 422 may be used.

The apparatus 420 is similar to the apparatus 400 of FIG. 4A and only differences will be discussed in detail. FIG. 4A and related description may be referenced for detail not repeated here.

A SALD head 422 is positioned on a side the flexible material 324 opposite the side at which the other SALD head 406, 408 is positioned. Accordingly, both sides of the flexible material 324 may be treated during the same pass of the flexible material along the path defined by the conveyance system 402.

The SALD head 422 may be positioned at the same leg of the path of the flexible material 324 as another SALD head 408.

In various embodiments of the disclosed apparatus, other equipment may be located adjacent to one or more SALD heads to allow characterization or modification of the flexible material or characterization or modification of the different layers of the ultra-thin coating.

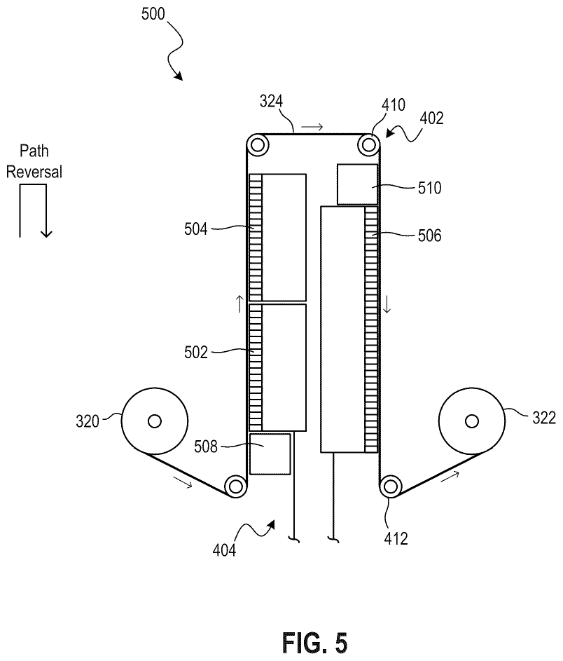

As shown in FIG. 5, an apparatus 500 includes a conveyance system 402 to transport a flexible substrate 324 along a path, a gas-delivery system 404 configured to deliver gas, and a plurality of SALD heads 502, 504, 506 to receive gas from the gas-delivery system 404 and provide the gas to the flexible substrate 324. Any suitable number and configuration of SALD heads 502, 504, 506 may be used.

The apparatus 500 is similar to the apparatus 400 of FIG. 4A and only differences will be discussed in detail. FIG. 4A and related description may be referenced for detail not repeated here.

First and second SALD heads 502, 504 are positioned on the same leg of the path followed by the flexible substrate 324. Third SALD head 506 is positioned on a different leg of the path.

A piece of equipment 508 is located adjacent to the first SALD head 502 and another piece of equipment 510 is located between the second and third SALD heads 504, 506, such that the flexible material 324 travels along the path past the first piece of equipment 508 before being coated by a first head 502 and travels past the second piece of equipment 510 after being coated by the first and second heads 502, 504 but before being coated by the third head 506. Examples of equipment 508, 510 that may be placed adjacent to the SALD heads 502, 504, 506 include, but are not limited to, web cleaning instruments (e.g., compressed air and exhaust to clear dust, deionizers, etc.), one or more plasma sources to clean or modify the surface energy of the surface of the flexible material for better coating adhesion, one or more plasma sources to clean the coated layers, one or more ellipsometers to characterize the coated layers, or one or more reflectance spectrometers to characterize the coated layers, or one or more other characterizing methods, and one or more quality assurance or quality control instruments to monitor the reliability of the coating process.

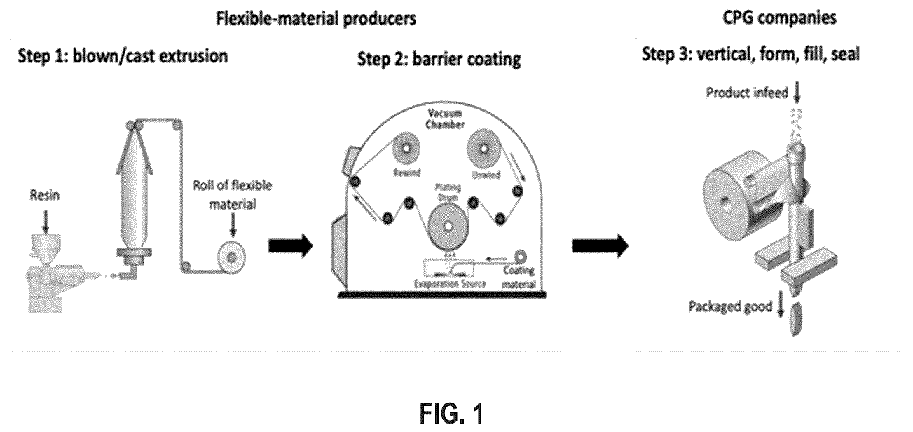

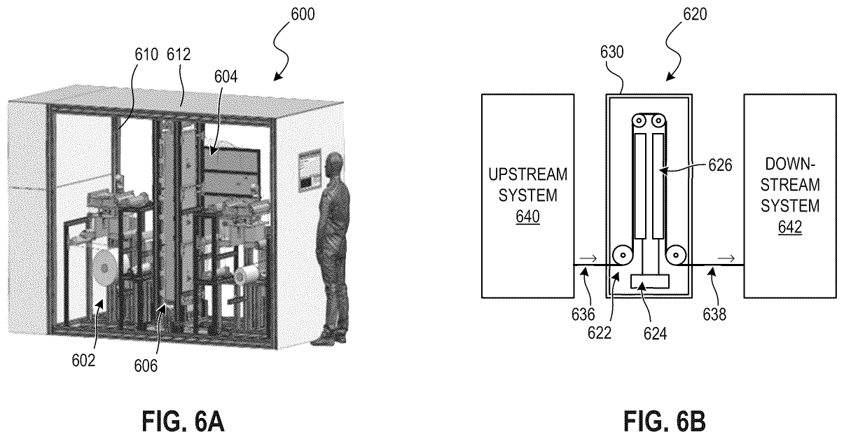

The disclosed apparatus may be a stand-alone system or a drop-in system that is integrated into a manufacturing line, as shown in FIGS. 6A and 6B. In various stand-alone embodiments, all components of the disclosed apparatus are attached to a frame and may be contained within a cabinet, with external connections including, but not limited to, power, gases, and/or exhaust, and the functional coatings are produced on flexible materials loaded into the cabinet. In various drop-in embodiments, one or more SALD heads from the disclosed apparatus are placed into a manufacturing line, and the other components of the disclosed apparatus (gas delivery system, exhaust pump(s), heater(s), etc.) may also be located within the manufacturing line or may be placed in proximity to the manufacturing line, with suitable connections between the different components. In various drop-in embodiments, a unit including a conveyance system, a gas-delivery system, and suitable number of SALD heads are attached to a frame (and may be contained within a cabinet) for drop-in to an existing production line. Inputs may include power and flexible material (if not provided by a unwinder roll also attached to the frame). Outputs include coated flexible material and exhaust gas. Comparing FIGS. 6A and 6B to FIG. 1, it should be understood that various embodiments of the disclosed apparatus can reduce or eliminate the need for a separate, batch, barrier-coating process in the flexible-packaging manufacturing process.

As shown in FIG. 6A, an example standalone apparatus 600 includes a conveyance system 602, a gas-delivery system 604, and SALD heads 606. The conveyance system 602, gas-delivery system 604, and SALD heads 606 may be attached to a frame 610 to secure the components together. The conveyance system 602, gas-delivery system 604, SALD heads 606, and frame 610 may be positioned into a container 612. For further detail concerning the conveyance system 602, gas-delivery system 604, and SALD heads 606, the description for FIGS. 4, 4A, 4B, and 5 may be referenced.

FIG. 6B shows an example drop-in apparatus 620 that includes a conveyance system 622, a gas-delivery system 624, and SALD heads 626. The conveyance system 622, gas-delivery system 624, and SALD heads 626 may be attached to a frame 630 to secure the components together. The assembly may be provided within a container for convenience. For further detail concerning the conveyance system 622, gas-delivery system 624, and SALD heads 626, the description for FIGS. 4, 4A, 4B, and 5 may be referenced. The frame 630 may be shaped and sized to fit within the physical constraints of the existing manufacturing line.

Input to the drop-in apparatus 620 may include a stream of flexible material 636 and electrical power. Output of the drop-in apparatus 620 may include a stream of coated flexible material 638 and exhaust gas. In various examples, a gas (precursor, reactant, and/or inert gas) used by the gas-delivery system 624 may also be provided as an input.

The apparatus 620 may be “dropped in” between an upstream system 640 and a downstream system 642 of a manufacturing line. An example upstream system 640 is a blown or cast film extrusion system that forms the flexible material 636. An example downstream system 642 is a form, fill, and seal system to package a product with the coated flexible material 638. Other examples that may be used as upstream and/or downstream systems 640, 642 include a primer/anchor coating machine, a lamination machine, a top-coating/lacquer/varnish coating machine, a printing machine, a slitting machine, etc. The frame 630 may be specifically shaped and sized and the conveyance system 622, gas-delivery system 624, and SALD heads 626 may be specifically configured and positioned at the frame 630 to fit within the physical constraints of an existing manufacturing line. A particular shape, size, and configuration of the apparatus 620 may be used with a range of manufacturing lines that share physical constraints.

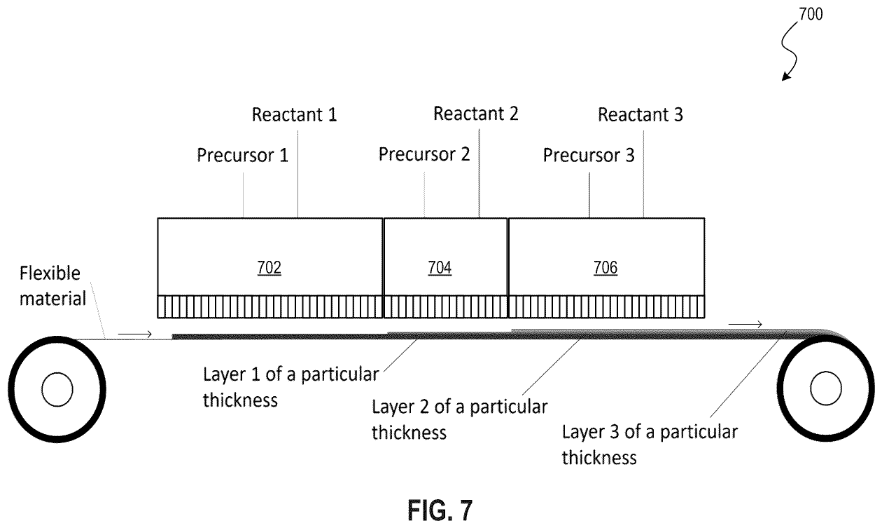

With reference to FIGS. 3 and 7, internal gas channels and output slits of a SALD head may be modular in nature. The gas channels and slits may be arranged such that a flexible material moving next to the reactor is sequentially exposed to precursor and reactor chemicals, resulting in SALD, as illustrated in FIG. 2. One or more SALD heads can have different numbers and configurations of modular gas channels and slits to enable deposition of different layer thicknesses. Different precursor and/or reactant chemicals may be delivered by the gas delivery system to different gas channels, so that different materials may be deposited. This enables multi-layer coatings.

FIG. 7 shows an example embodiment of an apparatus 700, where three different combinations of precursor and reactant gases are delivered to different numbers of distinct gas channels and slits in respective SALD heads 702, 704, 706, which may result in the deposition of a functional coating comprised of three layers, each of which may be a different thickness and a different material. Other aspects of the apparatus may also be adjusted to control the thickness and composition of each layer deposited, including, but not limited to, the speed at which the flexible material is moved relative to the SALD heads 702, 704, 706, the flow rates of the gases provided to the SALD heads 702, 704, 706, and the number of cycles provided by each respective SALD head 702, 704, 706. A cycle is the coating material deposited by a particular gas-output slit of a SALD head 702, 704, 706. When a SALD head 702, 704, 706 includes a number of slits that deliver the same gas, then the head can be said to provide the same number of cycles. A layer may be made of a number of cycles. For example, if a SALD head 702 has ten slits for precursor gas A, then the layer of coating A may have a thickness that corresponds to the ten cycles. Likewise, if SALD head 704 has five slits for precursor gas B, then the layer of coating B may have a thickness that corresponds to the five cycles.

The apparatus 700 may include a first SALD head 702 with a first configuration of gas channels and output slits to deliver a first precursor gas and/or first reactant gas to the surface of the flexible material. The apparatus 700 may further include a second SALD head 704 with a second configuration of gas channels and output slits to deliver second precursor gas and/or second reactant gas to the surface of the flexible material. The second SALD head 704 may be positioned downstream, with respect to direction of motion of the flexible material, to the first SALD head 702. The apparatus 700 may further include a third SALD head 706 with a third configuration of gas channels and output slits to deliver a third precursor gas and/or third reactant gas to the surface of the flexible material. The third SALD head 706 may be positioned downstream, with respect to direction of motion of the flexible material, to the second SALD head 704. First, second, and third configurations may be different.

The principles described for the apparatus 700 may be used with the embodiments discussed with respect to FIGS. 3, 4A, 4B, 5, 6A, and GB. The description related to FIGS. 3, 4A, 4B, 5, 6A, and 6B may be referenced for detail not repeated above for the apparatus 700.

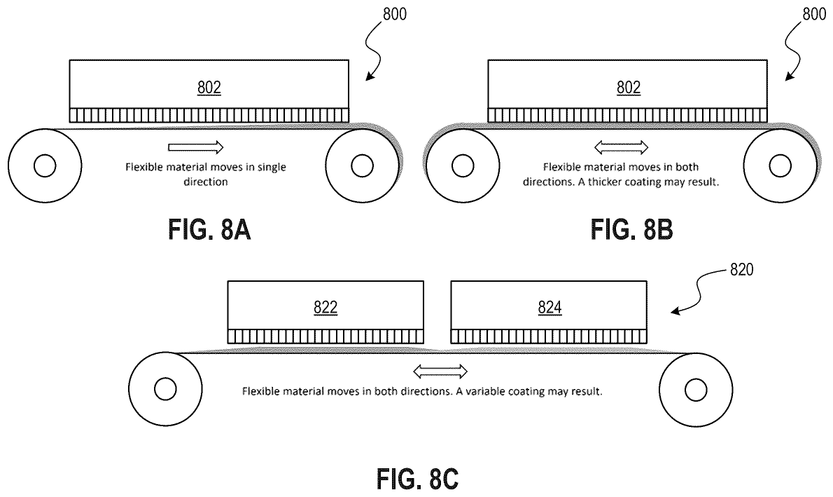

As shown in FIGS. 8A, 8B, and 8C, various conveyance systems discussed herein may enable the flexible material to move in a single direction relative to one or more SALD heads or in both directions relative to one or more SALD heads.

As shown in FIG. 8A, an apparatus 800 may include rollers that may be operated in a manner to move the flexible material in one direction at a constant speed relative to a SALD head 802.

As shown in FIG. 8B, the rollers of the apparatus 800 may be operated in a manner to move the flexible material in both directions relative to the SALD head 802, which may result in the deposition of thicker coatings onto the flexible material by oscillating the flexible material past the SALD head 802 any suitable number of times.

As shown in FIG. 8C, an apparatus 820 may include rollers operated in a manner to move the flexible material in both directions relative to two (or more) SALD heads 822, 824, which may result in the deposition of thicker coatings on the flexible material (e.g., by oscillating the flexible material past the SALD heads) and/or coatings with variable thickness and/or composition (e.g., by exposing different portions of the flexible material to the different heads for different durations).

The principles described for the apparatuses 800, 820 may be used with the embodiments discussed with respect to FIGS. 3, 4A, 4B, 5, 6A, 6B, and 7. The description related to FIGS. 3, 4A, 4B, 5, 6A, 6B, and 7 may be referenced for detail not repeated above for the apparatuses 800, 820.

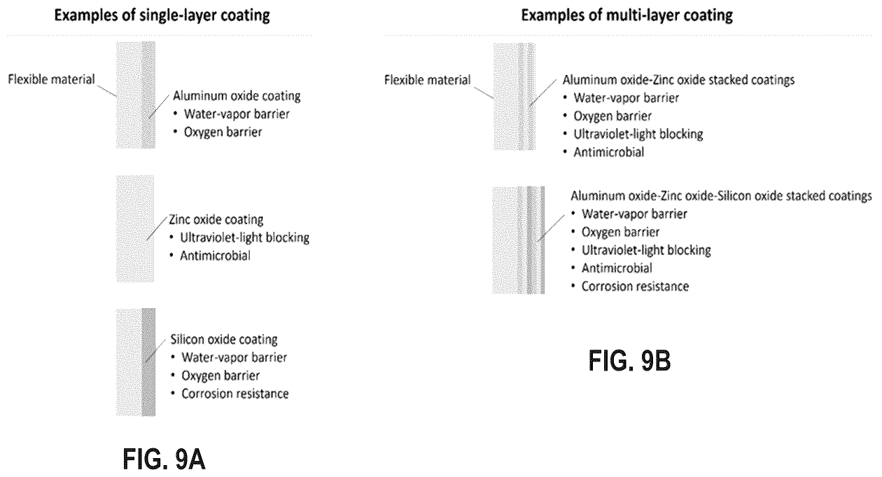

The apparatuses and methods discussed enable a functional coating to be applied directly (with or without a primer layer, anchor layer, or tie layer) on flexible materials such as polyethylene, polypropylene, polylactic acid, paperboard and paper, or a combination thereof, but not limited to the stated. The coating material may be a metal oxide, but other compositions such as metals, metal nitrides, metal alkoxides, metal sulfides, multi-component alloys, and doped materials may also be used. The functional coating typically has a thickness on the order of 10 to 100 nanometers but is not limited to the stated thicknesses. In the disclosed apparatus and method, the number of gas channels in one or more SALD heads, the number of precursor and/or reactant chemicals delivered by the gas channels, and the sequence in which the flexible material is exposed to the gas channels can be varied, enabling single-layer (FIG. 9A) and multi-layer thin-film coatings (FIG. 9B). A single-layer functional coating composed of one type of coating material (e.g., aluminum oxide) of variable thickness is disclosed. A multi-layer (or nanolaminate) functional coating is also disclosed. The multi-layer functional coating may comprise two or more coating materials (e.g., aluminum oxide, zinc oxide, tin oxide, silicon oxide, titanium dioxide). Alternatively, the multi-layer coating may be comprised one coating material (e.g., aluminum oxide), where the properties of the material are varied between the different layers using techniques such as, but not limited to, doping some of the layers with small quantities of additional elements, varying the deposition conditions used for some of the layers (e.g., deposition temperature), varying the ratio of precursor and reactant chemicals used, and varying the type of precursor or reactant. The multi-layer functional coatings may have any number of layers and these layers may be deposited in any sequence, including repeating patterns (e.g., repeating aluminum oxide-zinc oxide-tin oxide layers). Furthermore, each layer within the multi-layer coating can have any thickness on the order of tens of nanometers or less.

The disclosed single-layer coatings may have multiple functions, depending on the coating material and coating properties (e.g., thickness and roughness). Functions include, but are not limited to, water-barrier properties, water-vapor-barrier properties, oxygen-barrier properties, grease-barrier properties, aroma-barrier properties, light-blocking, corrosion resistance, transparency for product-viewing, antimicrobial properties, retortability, friction reduction, energy harvesting, sensing, display features, anti-counterfeiting, and tampering detection. Examples of single-layer functional coatings are illustrated in FIG. 9A. Various embodiments include an aluminum-oxide coating with water-vapor-barrier and/or oxygen-barrier functions. Another embodiment is a zinc-oxide coating with ultraviolet-light-blocking and/or antimicrobial functions. Another embodiment is a silicon-oxide coating with water-vapor-barrier, oxygen barrier, and corrosion-resistance functions.

The disclosed multi-layer barrier coatings may have multiple functions, which may include, but are not limited to, water-barrier properties, water-vapor-barrier properties, oxygen-barrier properties, grease-barrier properties, aroma-barrier properties, light-blocking, corrosion resistance, transparency for product-viewing, corrosion resistance, antimicrobial properties, retortability, friction reduction, energy harvesting, sensing, display features, anti-counterfeiting, and tampering detection. Multi-layer coatings can further enhance a moisture and/or oxygen barrier by inhibiting cracks that may occur due to flexure of the substrate. Examples of multi-layer functional coatings are illustrated in FIG. 9B. Various embodiments include an aluminum oxide-zinc oxide stacked coating with water-vapor-barrier and/or oxygen-barrier and/or ultraviolet-light-blocking and/or antimicrobial functions. Another embodiment is an aluminum oxide-zinc oxide-silicon oxide stacked coating with water-vapor-barrier and/or oxygen-barrier and/or ultraviolet-light-blocking and/or antimicrobial and/or corrosion-resistance functions.

According to further embodiments of the disclosure, the disclosed functional coatings may be combined with other functional layers or materials deposited using other techniques. For example, luminescent films, metal circuitry or nanoparticles deposited by techniques such as inkjet printing, screen-printing, and gravure coating may be placed on top of the disclosed functional coatings and/or underneath the disclosed functional coatings on the flexible packaging material and/or embedded within the disclosed functional coatings.

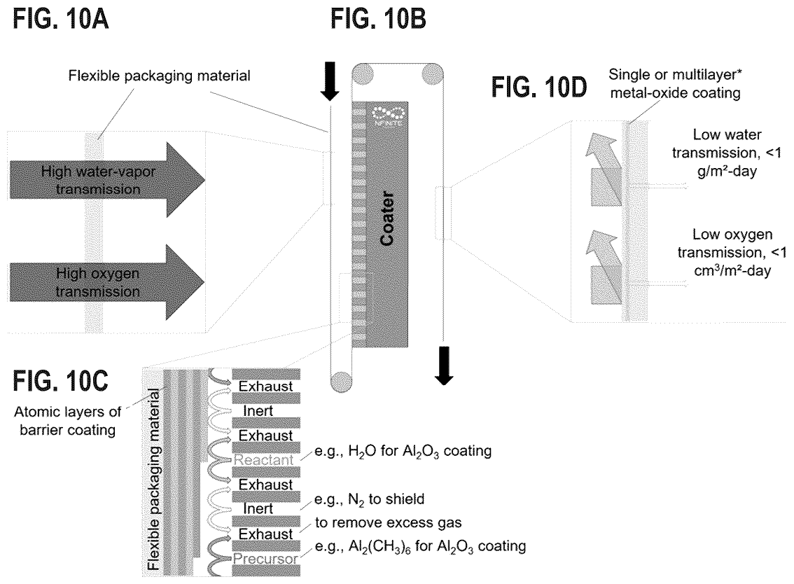

FIGS. 10A-10D are diagrams showing the adding of metal-oxide barrier coatings onto flexible packaging materials. FIG. 10A shows an uncoated flexible packaging material that inherently has poor barrier performance. The barrier performance here could be characterized by the water-vapor-transmission rate and oxygen-transmission rate, which measure how much moisture and oxygen pass through the flexible material per square meter of area per day. However, other barriers may also include, but are not limited to, grease, light and aroma barriers. FIG. 10B shows the flexible packaging material passing next to a SALD head to add the barrier coating. FIG. 10C shows the SALD coating process of this disclosure enabled with the techniques discussed with respect to FIGS. 3, 4A, 4B, 5, 6A, 6B, 7, 8A, 8B, 8C, 9A, and 9B. When the flexible packaging material passes by the SALD head, it gets exposed to different chemicals, typically, but not limited to, those in gaseous form. Approximately one atomic layer of the coating is formed by sequential reactions of a precursor chemical (e.g. trimethylaluminum, Al₂(CH₃)₆, for aluminum oxide) and reactant chemical (e.g., an oxidant such as H₂O) on the surface of the packaging material. Different precursor and reactant chemicals can be employed for different coating materials and to control the properties of the barrier coating. The precursor(s) and reactant(s) may be delivered by a carrier gas, such as nitrogen, and are delivered out of parallel channels in the head that extend across the surface of the flexible material. As shown in FIG. 10C, an inert gas (e.g., nitrogen) is also delivered from dedicated head channels to the surface of the flexible packaging material. The inert gas acts as a gas curtain to spatially separate the precursor and reactant chemicals and prevent them from mixing and reacting before reaching the surface of the packaging material. Exhaust channels may also be included in the head to remove gases from the space between the surface of the head and surface of the flexible material. Spatial separation of the precursor and reactant chemicals enables sequential chemical reactions on the surface of the flexible material so that the coating can be added approximately one atomic layer at a time, providing precise control over the coating thickness. FIG. 10D illustrates the coated flexible packaging material wherein the barrier performance is improved.

The disclosed metal-oxide barrier coatings contain a low density of pinholes, or may be pinhole-free, so they provide superior barrier properties to protect the products that are packaged within the flexible material or materials. Barrier typically refers to water-vapor barrier or oxygen barrier but is not limited to the stated. These barrier properties prevent moisture, oxygen, and other external elements from entering the package to keep the products fresh and may extend the shelf life of products, such as food.

The disclosed metal-oxide barrier coatings are only a few tens of nanometers thick, such that they do not affect the compostability and/or biodegradability and/or recyclability of sustainable packaging materials. Due to their ultra-thin nature, disclosed coatings also do not significantly affect the mechanical flexibility of the packaging materials.

Compared to conventional barrier-coating processes, as seen in FIG. 1, the disclosed invention operates in open-air without a vacuum chamber, reducing capital and/or operational costs of the process and increasing its speed, throughput, and/or productivity. The disclosed method is also solvent free.

Although the present disclosure has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present disclosure.

In the preceding description, for purposes of explanation, numerous details are set forth in order to provide a thorough understanding of the embodiments. However, it will be apparent to one skilled in the art that these specific details may not be required. In other instances, well-known structures may be shown in block diagram form in order not to obscure the understanding. For example, specific details are not provided as to whether elements of the embodiments described herein are implemented as a software routine, hardware circuit, firmware, or a combination thereof.

The terminology used herein is for the purpose of describing specific embodiments only and is not intended to be limiting of the system or disclosure. As used herein, the term “and/or” includes any and all combinations of one or more of the associated listed items. As used herein, the singular forms “a,” “an, “and “the” are intended to include the plural forms as well as the singular forms, unless the context clearly indicates otherwise. It will be further understood that the terms “comprise(s)” and/or “comprising,” when used in this specification, specify the presence of stated features, steps, operations, elements, and/or components, but do not preclude the presence or addition of one or more other features, steps, operations, elements, components, and/or groups thereof.

1. An apparatus comprising:
a conveyance system to transport a flexible substrate along a path;
a gas-delivery system configured to deliver gas to the flexible substrate;
a first spatial atomic layer deposition (SALD) head connected to the gas-delivery system to deliver gas to the flexible substrate, wherein the first SALD head includes a slit positioned adjacent to the path to deliver gas to the flexible substrate under atmospheric conditions; and
a second SALD head connected to the gas-delivery system to deliver gas to the flexible substrate, wherein the second SALD head includes a slit positioned adjacent to the path to deliver gas to the flexible substrate under atmospheric conditions;
wherein the first and second SALD heads are arranged along the path to deliver gas to the flexible substrate in sequence to apply a coating to the flexible substrate as the flexible substrate is transported along the path.

2. The apparatus of claim 1, wherein the first and second SALD heads are arranged to deliver gas to a same side of the flexible substrate.

3. The apparatus of claim 1, wherein the first and second SALD heads are arranged to deliver gas to different sides of the flexible substrate.

4. The apparatus of claim 1, wherein the conveyance system is configured to define a reversal in the path.

5. The apparatus of claim 4, wherein the first and second SALD heads are positioned at a same leg of the reversal.

6. The apparatus of claim 4, wherein the first and second SALD heads are positioned at different legs of the reversal.

7. The apparatus of claim 4, wherein the reversal is about 180 degrees.

8. The apparatus of claim 1, wherein the gas-delivery system and the first and second SALD heads are configured to apply gas to form a same layer of the coating.

9. The apparatus of claim 1, wherein the gas-delivery system and the first and second SALD heads are configured to apply gas to form different layers of the coating.

10. The apparatus of claim 1, further comprising a frame to which the conveyance system, gas-delivery system, and first and second SALD heads are attached, wherein the frame is shaped and sized to be dropped into an existing manufacturing line.

11. A method comprising:
arranging a first spatial atomic layer deposition (SALD) head and a second SALD head along a path of transport of a flexible substrate;
transporting the flexible substrate along the path; and
delivering, in sequence, gas to the flexible substrate with the first and second SALD heads under atmospheric conditions to apply a coating to the flexible substrate as the flexible substrate is transported along the path.

12. The method of claim 11, further comprising arranging the first and second SALD heads to deliver gas to a same side of the flexible substrate.

13. The method of claim 11, further comprising arranging the first and second SALD heads to deliver gas to different sides of the flexible substrate.

14. The method of claim 11, further comprising positioning the first and second SALD heads at a same leg of a reversal in the path.

15. The method of claim 11, further comprising positioning the first and second SALD heads at different legs of a reversal in the path.

16. The method of claim 11, further comprising delivering, in sequence, gas to the flexible substrate with the first and second SALD heads under atmospheric conditions to form a same layer of the coating.

17. The method of claim 11, further comprising delivering, in sequence, gas to the flexible substrate with the first and second SALD heads under atmospheric conditions to form different layers of the coating.

18. The method of claim 11, further comprising attaching the first and second SALD heads to a frame and installing the frame and installed first and second SALD heads into an existing manufacturing line.
